(19) United States
(12) Patent Application Publication
(10) Pub. No.: US 2023/0170432 A1
(43) Pub. Date: Jun. 1, 2023

(54) PHOTOSENSITIVE DEVICE SUBSTRATE

(71) Applicant: AUO Corporation, Hsinchu (TW)

(72) Inventors: Chia-Hsiu Tsai, Hsinchu (TW); Chia-Ming Chang, Hsinchu (TW); Ruei-Pei Chen, Hsinchu (TW)

(73) Assignee: AUO Corporation, Hsinchu (TW)

(21) Appl. No.: 17/898,404

(22) Filed: Aug. 29, 2022

(30) Foreign Application Priority Data
Nov. 26, 2021 (TW) 110144170

(51) Int. Cl. H01L 31/105; H01L 31/0224; H01L 31/0328; H01L 31/109

(52) U.S. Cl. CPC H01L 31/1055; H01L 31/109; H01L 31/0328; H01L 31/022408

(57) ABSTRACT

A photosensitive device substrate including a substrate, an active device, and a photosensitive device is provided. The active device and the photosensitive device are disposed on the substrate. The active device has a semiconductor pattern and a gate electrode. The semiconductor pattern is disposed between the substrate and the gate electrode. The photosensitive device is electrically connected to the active device. The photosensitive device has a photoelectric conversion layer and a first electrode and second electrode disposed on two opposite sides of the photoelectric conversion layer. The first electrode is located between the photoelectric conversion layer and the semiconductor pattern, and the material of the first electrode includes a metal oxide.

### CROSS-REFERENCE TO RELATED APPLICATION

This application claims the priority benefit of Taiwan application serial no. 110144170, filed on Nov. 26, 2021. The entirety of the above-mentioned patent application is hereby incorporated by reference herein and made a part of this specification.

### BACKGROUND

### Technical Field

The disclosure relates to a sensing substrate, and more particularly, to a photosensitive device substrate.

### Description of Related Art

The application of photo sensors is very wide. Commonly used in digital cameras or video cameras are image sensors, such as complementary metal-oxide-semiconductor (CMOS) image sensors or charge-coupled devices (CCD). In addition, non-visible light (such as X-ray) sensors for security inspection, industrial inspection, or medical diagnosis have become key development projects of related manufacturers due to high added value thereof.

Generally speaking, X-ray sensors used for medical testing or surgery must have a high sensing frequency, so that the medical personnel may obtain a real-time state of the patient’s body therefrom, so as to increase the accuracy of detection and the success rate of surgery. Therefore, most of these sensors use thin film transistors with high electron mobility as switch devices. Metal-oxide-semiconductor transistors are favored due to low leakage currents and noise thereof. However, in a manufacturing process, operational electrical properties of a metal oxide semiconductor layer, such as a current-voltage curve (I-V curve), are easily changed by the influence of the reaction gas in the subsequent manufacturing process, resulting in poor electrical properties of the subsequently formed transistors.

### SUMMARY

The disclosure provides a photosensitive device substrate with a high sensing frequency, which has better operational electrical properties and stability.

A photosensitive device substrate in the disclosure includes a substrate, an active device, and a photosensitive device. The active device and the photosensitive device are disposed on the substrate. The active device has a semiconductor pattern and a gate electrode. The semiconductor pattern is disposed between the substrate and the gate electrode. The photosensitive device is electrically connected to the active device. The photosensitive device has a photoelectric conversion layer and a first electrode and a second electrode disposed on two opposite sides of the photoelectric conversion layer. The first electrode is located between the photoelectric conversion layer and the semiconductor pattern, and a material of the first electrode comprises a metal oxide.

Based on the above, in the photosensitive device substrate according to the embodiment of the disclosure, the first electrode of the photosensitive device on the side closer to the active device may be formed by the metal oxide, which may effectively block the process gas from penetrating into the semiconductor pattern of the active device, thereby affecting the operational electrical properties and stability of the previously formed active device.

### BRIEF DESCRIPTION OF THE DRAWINGS

FIG. 1 is a schematic cross-sectional view of a photosensitive device substrate according to the first embodiment of the disclosure.

FIG. 2 is a schematic cross-sectional view of a photosensitive device substrate according to the second embodiment of the disclosure.

FIG. 3 is a schematic cross-sectional view of a photosensitive device substrate according to the third embodiment of the disclosure.

FIG. 4 is a schematic cross-sectional view of a photosensitive device substrate according to the fourth embodiment of the disclosure.

### DETAILED DESCRIPTION OF DISCLOSED EMBODIMENTS

The term “about”, “approximately”, “essentially” or “substantially” used herein includes the value and an average value within an acceptable deviation range of specific values determined by a person of ordinary skill in the art, taking into account discussed measurements and a specific number of measurement-related errors (i.e., limitations of a measuring system). For example, the term “about” may mean being within one or more standard deviations of the value, or within, for example, ±30%, ±20%, ±10%, and ±5%. Moreover, the term “about”, “approximately”, “essentially” or “substantially” used herein may mean selecting a more acceptable deviation range or standard deviations according to measurement properties, cutting properties or other properties, without applying a single standard deviation to all properties.

In the accompanying drawings, thicknesses of layers, films, panels, regions, etc., are enlarged for clarity. It should be understood that when a device such as the layer, film, region, or substrate is described as being “on” or “connected to” another device, it may be directly on or connected to another device, or there may be an intervening device therebetween. In contrast, when a device is described as being “directly on” or “directly connected to” another device, there are no intervening devices therebetween. As used herein, “connected” may refer to a physical and/or electrical connection. Furthermore, “electrically connected” may refer to the existence of other devices between the two devices.

Reference will now be made in detail to the exemplary embodiments of the disclosure, and examples of the exemplary embodiments are illustrated in the accompanying drawings. Whenever possible, the same reference numerals are used in the drawings and descriptions to indicate the same or similar parts.

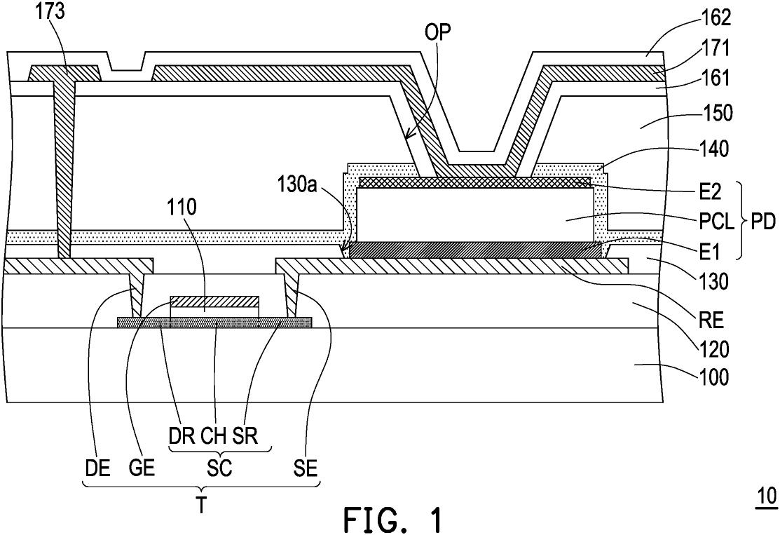

FIG. 1 is a schematic cross-sectional view of a photosensitive device substrate according to the first embodiment of the disclosure. Referring to FIG. 1, a photosensitive device substrate 10 includes a substrate 100, an active device T, and a photosensitive device PD. The active device T and the photosensitive device PD are disposed on the substrate 100 and are electrically connected to each other. It should be noted that, although not shown in the drawings, the number of the photosensitive devices PD and the active devices T in this embodiment may be multiple respectively and disposed in an array on the substrate 100.

In this embodiment, a method of forming the active device T may include the following steps. A semiconductor pattern SC, a gate insulating layer 110, a gate electrode GE, an interlayer insulating layer 120, a source electrode SE, and a drain electrode DE are sequentially formed on the substrate 100. The semiconductor pattern SC has a channel region CH, a source region SR, and a drain region DR, and the source electrode SE and the drain electrode DE penetrate through the interlayer insulating layer 120 to be electrically connected to the source region SR and the drain region DR of the semiconductor pattern SC, respectively. In this embodiment, the gate electrode GE of the active device T may be optionally disposed above the semiconductor pattern SC (that is, the semiconductor pattern SC is disposed between the gate electrode GE and the substrate 100 ) to form a top-gate thin film transistor (top-gate TFT), but the disclosure is not limited thereto. According to other embodiments, the gate electrode GE of the active device may also be disposed below the semiconductor pattern SC to form a bottom-gate thin film transistor (bottom-gate TFT).

A material of the semiconductor pattern SC is, for example, an indium gallium zinc oxide (IGZO), or other metal oxides with high electron mobility. That is, the active device T is, for example, a metal-oxide thin film transistor. It should be noted that the gate electrode GE, the source electrode SE, the drain electrode DE, the gate insulating layer 110, and the interlayer insulating layer 120 may be respectively implemented by any gate electrode, any source electrode, any drain electrode, any interlayer insulating layer, and any gate insulating layer for a display panel known to any one of ordinary skill in the art. In addition, the gate electrode GE, the source electrode SE, the drain electrode DE, the gate insulating layer 110 and the interlayer insulating layer 120 may be respectively formed by any method known to any one of ordinary skill in the art. Thus, details in this regard will not be further reiterated in the following.

Since a semiconductor material with high electron mobility is adopted for the active device T in this embodiment, the photosensitive device substrate 10 may be applied to a medical X-ray sensing panel. For example, the X-ray sensing panel may include the photosensitive device substrate 10 and a wavelength conversion layer, and the wavelength conversion layer is disposed on a light-receiving side of the photosensitive device substrate 10 and overlaps the photosensitive devices PD. A material of the wavelength conversion layer here is, for example, cesium iodide (CsI), which emits visible light (such as green light) after absorbing the incident X-ray, and the photosensitive device PD is adapted to receive the visible light and generate a corresponding electrical signal.

Further, a method of forming the photosensitive device PD may include the following steps. An insulating layer 130, a first electrode E1, a photoelectric conversion layer PCL, and a second electrode E2 are sequentially formed on the active device T. In this embodiment, a material of the insulating layer 130 may be selected from inorganic materials (e.g., silicon oxide, silicon nitride, silicon oxynitride, other suitable materials, or a stacked layer of at least two of the above materials). A material of the first electrode E1 includes the metal oxide, such as the indium gallium zinc oxide (IGZO). A material of the second electrode E2 includes a transparent conductive material, such as an indium tin oxide (ITO) or an indium zinc oxide (IZO).

The photoelectric conversion layer PCL is, for example, a PIN junction structure formed by stacking a P-type doped layer, an intrinsic layer, and an N-type doped layer, but the disclosure is not limited thereto. In other embodiments, the photoelectric conversion layer PCL may also be a PN junction structure formed by stacking the P-type doped layer and the N-type doped layer or a tandem structure in which the PN junction structure and the PIN junction structure are repeatedly arranged.

In particular, in this embodiment, a material of the photoelectric conversion layer PCL is, for example, hydrogenated amorphous silicon (a-Si:H). In a deposition process of the hydrogenated amorphous silicon, reaction gases such as silane (SiH4) and hydrogen gas (H2), which easily penetrate other film layers, are used, and in a subsequent annealing process of the second electrode E2, hydrogen atoms in a hydrogenated amorphous silicon material layer are also easily diffused to other film layers, such as the previously formed semiconductor pattern SC. As a result, operational electrical properties of the previously formed active device T are affected.

In order to effectively block the penetration of hydrogen gas or the diffusion of hydrogen atoms, the material of the first electrode E1 located between the photoelectric conversion layer PCL and the semiconductor pattern SC may be formed by the metal oxide (e.g., the indium gallium zinc oxide). In particular, conductivity of the indium gallium zinc oxide will increase after absorbing hydrogen. Therefore, the indium gallium zinc oxide is used to manufacture the first electrode E1, which may not only effectively block hydrogen of the photoelectric conversion layer PCL from diffusing to the semiconductor pattern SC, but also meet conductivity requirements for the first electrode E1.

On the other hand, a material of the gate electrode GE disposed above the semiconductor pattern SC may also be formed by the indium gallium zinc oxide. Therefore, the penetration of hydrogen gas into the semiconductor pattern SC in a deposition process of the photoelectric conversion layer PCL may be further blocked, thereby affecting the operational electrical properties of the active device T.

In this embodiment, the photosensitive device substrate 10 may also optionally include a reflective electrode RE, which is disposed between the first electrode E1 and the active device T, and overlaps the photoelectric conversion layer PCL along a direction perpendicular to the substrate 100. The reflective electrode RE is electrically connected between the first electrode E1 and the source electrode SE of the active device T. For example, the reflective electrode RE, the source electrode SE, and the drain electrode DE may belong to the same film layer, but the disclosure is not limited thereto. A material of the reflective electrode RE is, for example, metal, alloy, nitride of a metal material, oxide of the metal material, nitrogen oxide of the metal material, other conductive materials with high reflectivity, or a stacked layer of the metal material and other conductive materials.

In detail, the insulating layer 130 has an opening 130a overlapping the reflective electrode RE, and the first electrode E1 of the photosensitive device PD is disposed in the opening 130a and is in direct contact with the reflective electrode RE. It should be noted that a contact area between the first electrode E1 and the reflective electrode RE is greater than a contact area between the first electrode E1 and the photoelectric conversion layer PCL. Accordingly, in addition to increasing photoelectric conversion efficiency of the photosensitive device PD, the conductivity between the first electrode E1 of the photosensitive device PD and the source electrode SE of the active device T may also be improved.

Further, the photosensitive device substrate 10 further includes an insulating layer 140, a planarization layer 150, an insulating layer 161, an insulating layer 162, and a metal conductive layer. The insulating layer 140 and the planarization layer 150 sequentially cover the photosensitive device PD and the insulating layer 130, and have an opening OP overlapping the photosensitive device PD. The insulating layer 161, the metal conductive layer, and the insulating layer 162 are sequentially disposed on the planarization layer 150. In this embodiment, the metal conductive layer may include a conductive pattern 171 and a conductive pattern 173. The conductive pattern 171 extends into the opening OP of the planarization layer 150 and the insulating layer 140, and is electrically connected to the second electrode E2 of the photosensitive device PD. The conductive pattern 173 penetrates through the insulating layer 161, the planarization layer 150, the insulating layer 140, and the insulating layer 130 to be electrically connected to the drain electrode DE of the active device T.

For example, the conductive pattern 171 and the conductive pattern 173 may be electrically connected to different signal lines to respectively transmit a bias signal required by the photosensitive device PD and the electrical signal generated by the photosensitive device PD after receiving the light, but the disclosure is not limited thereto. It should be noted that in the disclosure, the number of the metal conductive layers and the insulating layers is not limited. In other embodiments, the number of the metal conductive layers and the insulating layers may be adjusted according to actual circuit design requirements.

In this embodiment, the insulating layer 140, the planarization layer 150, the insulating layer 161, and the insulating layer 162 may be selected from the inorganic materials (e.g., silicon oxide, silicon nitride, silicon oxynitride, other suitable materials, or a stacked layer of at least two of the above materials). A material of the planarization layer 150 may be selected from silicon oxide, silicon nitride, aluminum oxide, silicon oxynitride, and other suitable materials. A material of an organic material layer may be selected from poly(vinyl pyrrolidone) (PVP), polyvinyl alcohol (PVA), poly(methyl methacrylate) (PMMA), ethylene-tetrafluoroethylene (ETFE), fluorinated ethylene propylene (FEP), poly(vinylidene fluoride) (PVDF), polyvinyl fluoride (PVF), ethylene chlorotrifluoroethylene (ECTFE), polytetrafluoroethylene (PTFE), perfluoro(alkoxy alkane) (PFA), or other fluorine-based materials.

Some other embodiments are provided below to describe the disclosure in detail, where the same reference numerals denote the same or like components, and descriptions of the same technical contents are omitted. The aforementioned embodiment may be referred for descriptions of the omitted parts, and detailed descriptions thereof are not repeated in the following embodiment.

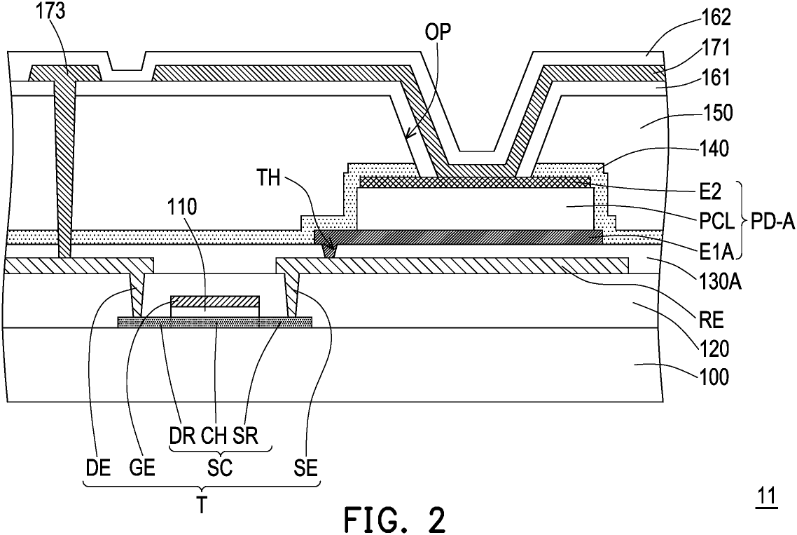

FIG. 2 is a schematic cross-sectional view of a photosensitive device substrate according to the second embodiment of the disclosure. Referring to FIG. 2, a difference between a photosensitive device substrate 11 in this embodiment and the photosensitive device substrate 10 in FIG. 1 is that the configuration of the first electrode of the photosensitive device is different. Specifically, an insulating layer 130A of the photosensitive device substrate 11 does not have the opening 130a in FIG. 1, but has a contact hole TH that does not overlap the photoelectric conversion layer PCL. The contact hole TH is located between the photoelectric conversion layer PCL and the active device T. In this embodiment, a first electrode E1A of a photosensitive device PD-A is electrically connected to the reflective electrode RE (or the source electrode SE) through the contact hole TH.

Since the material selection of the first electrode E1A in this embodiment and technical effect thereof are similar to those of the first electrode E1 in FIG. 1, relevant paragraphs of the foregoing embodiment may be referred for detailed descriptions, and the same details will not be repeated in the following.

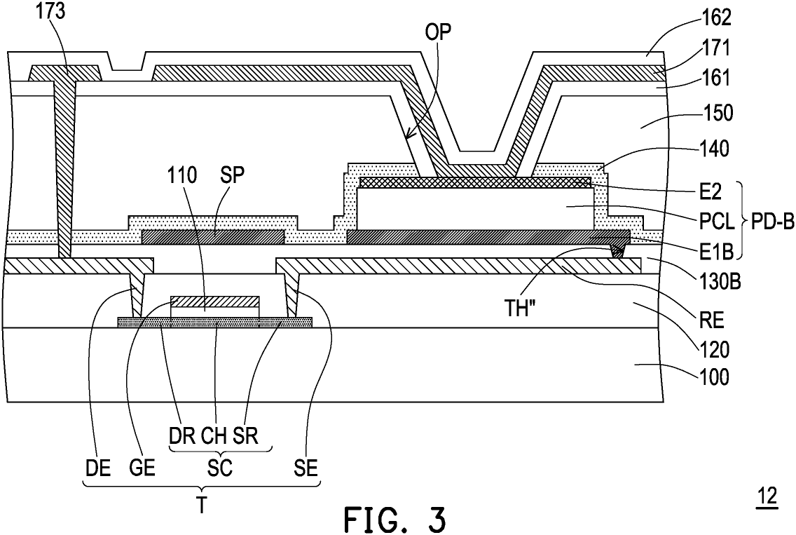

FIG. 3 is a schematic cross-sectional view of a photosensitive device substrate according to the third embodiment of the disclosure. Referring to FIG. 3, a main difference between a photosensitive device substrate 12 in this embodiment and the photosensitive device substrate 11 in FIG. 2 is that the photosensitive device substrate 12 may optionally include a sacrificial pattern SP. In this embodiment, the sacrificial pattern SP overlaps the semiconductor pattern SC and the gate electrode GE of the active device T along the direction perpendicular to the substrate 100. The semiconductor pattern SC and the gate electrode GE are located between the substrate 100 and the sacrificial pattern SP.

It should be noted that the sacrificial pattern SP and a first electrode E1B of a photosensitive device PD-B may be the same film layer. That is, materials of the sacrificial pattern SP and the first electrode E1B may be optionally the same. For example, the sacrificial pattern SP may also be formed by the indium gallium zinc oxide as the first electrode E1B. Therefore, the penetration of hydrogen gas into the semiconductor pattern SC in the deposition process of the photoelectric conversion layer PCL may be further blocked, thereby affecting the operational electrical properties of the active device T.

On the other hand, the sacrificial pattern SP and the first electrode E1B are electrically independent of each other. For example, the sacrificial pattern SP may have a floating potential. In order to avoid electrical short circuit between the first electrode E1B and the sacrificial pattern SP, a contact hole TH” of an insulating layer 130B in this embodiment may be changed to be disposed on one side of the photosensitive device PD-B away from the sacrificial pattern SP and not overlap the photoelectric conversion layer PCL, but the disclosure is not limited thereto.

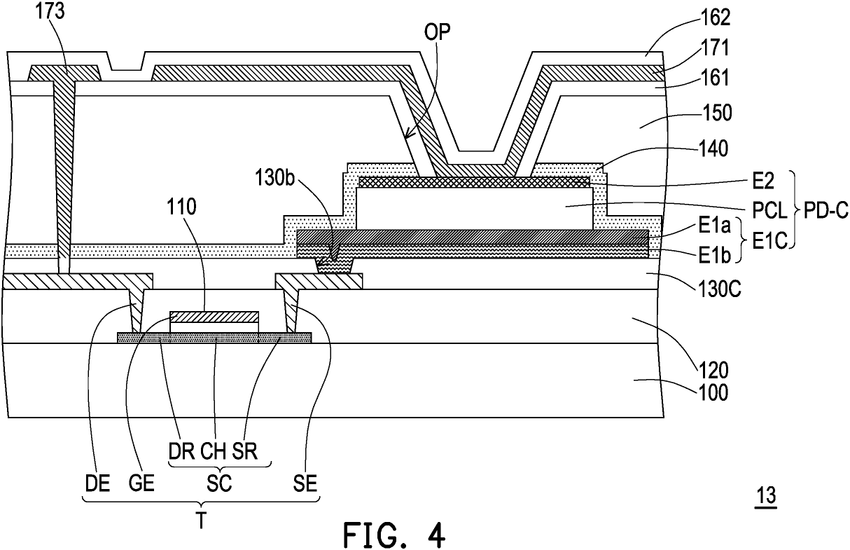

FIG. 4 is a schematic cross-sectional view of a photosensitive device substrate according to the fourth embodiment of the disclosure. Referring to FIG. 4 , a main difference between a photosensitive device substrate 13 in this embodiment and the photosensitive device substrate 11 in FIG. 2 is that a first electrode E1C of a photosensitive device PD-C of the photosensitive device substrate 13 is a stacked structure of a metal oxide conductive pattern E1a and a metal conductive pattern E1b, and the metal oxide conductive pattern E1a is disposed between the metal conductive pattern E1b and the photoelectric conversion layer PCL. Similar to the first electrode E1A in FIG. 2, the first electrode E1C in this embodiment may be electrically connected to the source electrode SE of the active device T through an opening 130b of an insulating layer 130C.

For example, the metal oxide conductive pattern E1a and the metal conductive pattern E1b may be formed by the indium gallium zinc oxide and molybdenum metal, respectively. Preferably, respective film thicknesses of the metal oxide conductive pattern E1a and the metal conductive pattern E1b may be greater than 30 nm. Since the metal conductive pattern E1b is formed by the molybdenum metal instead of alloy, in addition to increasing the conductivity of the entire first electrode E1C, it may further block hydrogen of the photoelectric conversion layer PCL from diffusing to the semiconductor pattern SC.

In addition, since the metal conductive pattern E1b in this embodiment has a characteristic of light reflection, the photosensitive device substrate 13 may omit the configuration of the reflective electrode RE in FIG. 2. In this embodiment, the metal oxide conductive pattern E1a and the metal conductive pattern E1b may be formed in the same patterning process (e.g., a photolithography process). That is, the metal oxide conductive pattern E1a and the metal conductive pattern E1b may be exposed and developed using the same mask. Accordingly, the photosensitive device substrate 13 in this embodiment may have a relatively simplified production process.

Based on the above, in the photosensitive device substrate according to the embodiment of the disclosure, the first electrode of the photosensitive device on the side closer to the active device may be formed by the metal oxide, which may effectively block the process gas from penetrating into the semiconductor pattern of the active device, thereby affecting the operational electrical properties and stability of the previously formed active device.

What is claimed is:

1. A photosensitive device substrate, comprising:
a substrate;
an active device disposed on the substrate and having a semiconductor pattern and a gate electrode, wherein the semiconductor pattern is disposed between the substrate and the gate electrode; and
a photosensitive device disposed on the substrate, electrically connected to the active device, and having a photoelectric conversion layer and a first electrode and a second electrode disposed on two opposite sides of the photoelectric conversion layer, wherein the first electrode is located between the photoelectric conversion layer and the semiconductor pattern, and a material of the first electrode comprises a metal oxide.

2. The photosensitive device substrate according to claim 1, wherein a material of the semiconductor pattern comprises an indium gallium zinc oxide.

3. The photosensitive device substrate according to claim 1, wherein a material of the first electrode comprises an indium gallium zinc oxide.

4. The photosensitive device substrate according to claim 1, wherein a material of the photoelectric conversion layer comprises hydrogenated amorphous silicon (a-Si:H).

5. The photosensitive device substrate according to claim 1, wherein a material of the gate electrode comprises an indium gallium zinc oxide.

6. The photosensitive device substrate according to claim 1, further comprising:
a reflective electrode disposed between the first electrode and the active device, and overlapping the photoelectric conversion layer, wherein the reflective electrode is electrically connected between the first electrode and a source electrode of the active device.

7. The photosensitive device substrate according to claim 6, wherein a contact area between the first electrode and the reflective electrode is greater than a contact area between the first electrode and the photoelectric conversion layer.

8. The photosensitive device substrate according to claim 1, further comprising:
a sacrificial pattern overlapping the gate electrode and the semiconductor pattern of the active device, wherein the semiconductor pattern and the gate electrode are located between the substrate and the sacrificial pattern, and a material of the sacrificial pattern comprises the metal oxide.

9. The photosensitive device substrate according to claim 8, wherein the material of the sacrificial pattern comprises an indium gallium zinc oxide.

10. The photosensitive device substrate according to claim 8, wherein the sacrificial pattern and the first electrode are a same film layer and are electrically independent of each other.

11. The photosensitive device substrate according to claim 8, wherein the sacrificial pattern has a floating potential.

12. The photosensitive device substrate according to claim 1, wherein the first electrode is a stacked structure of a metal conductive pattern and a metal oxide conductive pattern, and the metal oxide conductive pattern is disposed between the metal conductive pattern and the photoelectric conversion layer.

13. The photosensitive device substrate according to claim 12, wherein a material of the metal conductive pattern is molybdenum metal.
